(19) United States
(12) Patent Application Publication
(10) Pub. No.: US 2007/0063218 A1
(43) Pub. Date: Mar. 22, 2007

(54) SEMICONDUCTOR DEVICE AND ELECTROSTATIC DISCHARGE PROTECTION DEVICE

(76) Inventor: Chih-Cheng Liu, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,101

(22) Filed: Dec. 16, 2005

(30) Foreign Application Priority Data
Sep. 16, 2005 (TW) 94131989

(51) Int. Cl. H01L 29/74

(52) U.S. Cl. 257/173

(57) ABSTRACT

A semiconductor device is provided. The semiconductor device is suitable for an electrostatic discharge protection circuit. The semiconductor device includes a gate structure, an N-type source region, an N-type well region, an N-type drain region, and an N-doped region. Wherein, the gate structure comprises a gate and a gate oxide layer. The gate oxide layer is disposed between the gate and a substrate. In addition, the N-type source region is disposed in the substrate at one side of the gate, and the N-type well region is disposed in the substrate at another side of the gate. The N-type drain region is disposed in the substrate between the N-type well region and the gate structure. The N-type drain region has a first toothed part disposed in the N-type well region. The N-doped region is disposed in the N-type well region, and the N-doped region has a second toothed part.

### CROSS-REFERENCE TO RELATED APPLICATION

This application claims the priority benefit of Taiwan application serial no. 94131989, filed on Sep. 16, 2005. All disclosure of the Taiwan application is incorporated herein by reference.

### BACKGROUND OF THE INVENTION

1. Field of the Invention

The present invention relates to a semiconductor device, and more particularly, to a semiconductor device suitable for an electrostatic discharge protection circuit and an electrostatic discharge protection device.

2. Description of the Related Art

During the integrated circuit manufacturing process such as the DRAM (Dynamic Random Access Memory) and the SRAM (Static Random Access Memory) or after the chip is fabricated, the electrostatic discharge is usually the major reason contributing to the damage on the integrate circuit. For example, a static voltage of several hundreds or several thousands volts can be detected from a human body walking on the carpet with a higher relative humidity (RH). Moreover, a static voltage of higher than 10000 volts can be detected under a lower relative humidity (RH). When the object with static comes in contact with the chip, electrostatic is discharged to the chip, which causes the normal function of the chip to fail. For the most popular CMOS manufacturing process, such problem generated by the electrostatic discharge is particularly serious.

Accordingly, in order to prevent the chip from being damaged by the electrostatic discharge, various methods for protecting the electrostatic discharge are developed. Generally, an electrostatic discharge protection device is configured in the integrated circuit. The most popular method is by using a hardware device to prevent the electrostatic discharge. In other words, an electrostatic discharge protection circuit is designed and configured in the input/output port of the internal circuit.

FIG. 1 is a schematic diagram of a conventional electrostatic discharge protection circuit. Referring to FIG. 1, the electrostatic discharge protection circuit 10 is mainly composed of a PMOS transistor 12 and an NMOS transistor 14. Wherein, a gate of the PMOS transistor 12 is connected to a gate of the NMOS transistor 14, and both gates are also connected to an internal circuit 16. A drain of the PMOS transistor 12 is connected to a drain of the NMOS transistor 14, and both drains are also connected to an output pin 18. In addition, a source of the PMOS transistor 12 is connected to a power line VDD, and a source of the NMOS transistor 14 is connected to a power line VSS. When the electrostatic is discharging, the electrostatic discharge current is multiplexed by the turned-on NMOS transistor 14, so as to prevent the device damages by the high temperature of the current concentrating on one single part.

In addition, an N-well transistor is commonly used as an impedance of the output buffer. However, the N-well transistor usually takes a larger space in the integrated circuit. Moreover, a serious problem related to the protection of the electrostatic discharge occurs in the salicide manufacturing process. In other words, an uneven current is generated in the manufacturing process, which makes the electrostatic discharge unpredictable.

Accordingly, in the conventional technology, an island-type shallow trench isolation (STI) structure or a polysilicon structure is formed in the drain of the NMOS transistor for multiplexing the current flow. However, to make such island-type shallow trench isolation (STI) structure or the polysilicon structure not only complicates the manufacturing process, but also increases the manufacturing cost. Furthermore, when the electrostatic is discharging, the current concentrates on a single part and generates a high temperature thereon, which damages the structure of the integrated circuit.

### SUMMARY OF THE INVENTION

Therefore, it is an object of the present invention to provide a semiconductor device in which the current generated by the electrostatic discharge is evenly distributed.

The present invention provides a semiconductor device. The semiconductor device is suitable for an electrostatic discharge protection circuit. The semiconductor device comprises a gate structure, an N-type source region, an N-type well region, an N-type drain region, and an N-doped region. Wherein, the gate structure comprises a gate and a gate oxide layer. The gate oxide layer is disposed between the gate and a substrate. In addition, the N-type source region is disposed in the substrate at one side of the gate, and the N-type well region is disposed in the substrate at another side of the gate. The N-type drain region is disposed in the substrate between the N-type well region and the gate structure. The N-type drain region has a first toothed part disposed in the N-type well region. Furthermore, the N-doped region is disposed in the N-type well region, and the N-doped region has a second toothed part.

In the semiconductor device according to an embodiment of the present invention, a conductive layer is further included. The conductive layer is disposed on the N-type source region, a part of the gate, and a part of the N-doped region by which the second toothed part of the N-doped region is exposed.

In the semiconductor device according to the embodiment of the present invention, the conductive layer mentioned above is made of metal silicide, for example.

In the semiconductor device according to the embodiment of the present invention, a dielectric layer is further included. The dielectric layer disposed on the substrate covers the gate structure, the N-type source region, the N-type well region, the N-type drain region, the N-doped region, and the substrate.

In the semiconductor device according to the embodiment of the present invention, a drain contact plug is further included. The drain contact plug is disposed in the dielectric layer on the N-doped region.

In the semiconductor device according to the embodiment of the present invention, a source contact plug is further included. The source contact plug is disposed in the dielectric layer on the N-type source region.

In the semiconductor device according to the embodiment of the present invention, a pair of spacers are further included. The spacers are disposed on the side walls of the gate structure.

The present invention further provides an electrostatic discharge protection device. The electrostatic discharge protection device mainly comprises a PMOS transistor and an NMOS transistor. Wherein, a first gate of the PMOS transistor is electrically coupled to an internal circuit, and a source of the PMOS transistor is electrically coupled to a first power line. The NMOS transistor comprises a gate structure, an N-type source region, an N-type well region, an N-type drain region, and an N-doped region. The gate structure comprises a second gate and a gate oxide layer. Wherein, the gate oxide layer is disposed between the second gate and a substrate, and the second gate is electrically coupled to the first gate of the PMOS transistor. The N-type source region disposed in the substrate at one side of the gate structure is connected to a second power line. The N-type well region is disposed in the substrate at another side of the gate structure. The N-type drain region is disposed in the substrate between the N-type well region and the gate structure. Wherein, the N-type drain region is electrically coupled to a drain of the PMOS transistor, and both are connected to an output pin. The N-type drain region has a first toothed part disposed in the N-type well region. Furthermore, the N-doped region is disposed in the N-type well region, and the N-doped region has a second toothed part.

In the electrostatic discharge protection device according to an embodiment of the present invention, a conductive layer is further included. The conductive layer is disposed on the gate structure, the N-type source region, and the N-doped region by which the second toothed part of the N-doped region is exposed.

In the electrostatic discharge protection device according to the embodiment of the present invention, the conductive layer mentioned above is made of metal silicide, for example.

In the electrostatic discharge protection device according to the embodiment of the present invention, a dielectric layer is further included. The dielectric layer is disposed on the substrate.

In the electrostatic discharge protection device according to the embodiment of the present invention, a drain contact plug is further included. The drain contact plug is disposed in the dielectric layer on the N-doped region.

In the electrostatic discharge protection device according to the embodiment of the present invention, a source contact plug is further included. The source contact plug is disposed in the dielectric layer on the N-type source region.

An N-type well region with high impedance is disposed in the periphery of the N-doped region of the semiconductor device provided by the present invention. Accordingly, when the electrostatic is discharging, the current flowing through the electrostatic discharge protection circuit slows down. In addition, the N-type source region and the N-doped region in the present invention are formed in tooth shape, such that the current is evenly distributed when flowing through the circuit. With such design, the current does not concentrate on a single part that causes high temperature, and the structure of the integrated circuit device is not damaged by high temperature, which further improves the protection from the electrostatic discharge.

### BRIEF DESCRIPTION DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1 is a schematic diagram of a conventional electrostatic discharge protection circuit.

FIG. 2A is a top view of a semiconductor device according to an embodiment of the present invention.

FIG. 2B is a schematic cross-sectional view showing a semiconductor device from surface I-I′ in FIG. 1.

FIG. 3 is a schematic circuit diagram of an electrostatic discharge protection device according to an embodiment of the present invention.

### DESCRIPTION OF EMBODIMENTS

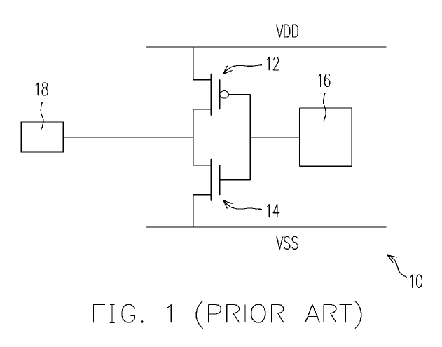

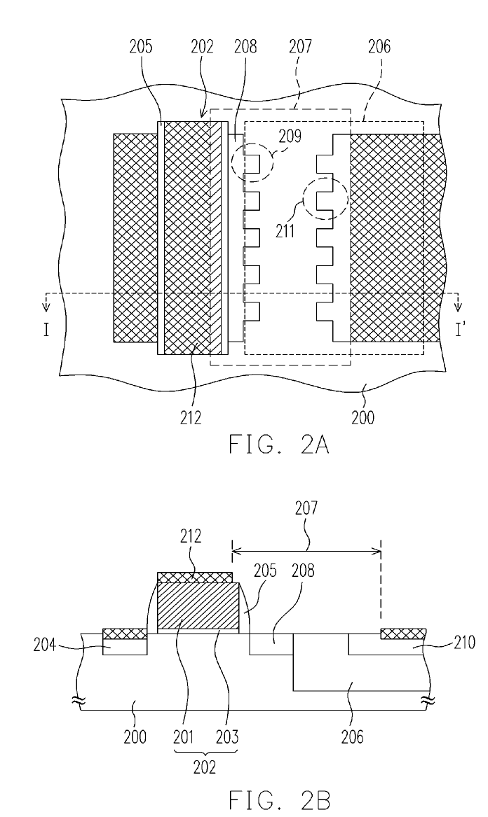

FIG. 2A is a top view of a semiconductor device according to an embodiment of the present invention. FIG. 2B is a schematic cross-sectional view showing a semiconductor device from surface I-I′ in FIG. 1.

Referring to FIGS. 2A and 2B, the semiconductor device of the present invention comprises a gate structure 202, an N-type source region 204, an N-type well region 206, an N-type drain region 208, and an N-doped region 210.

The gate structure 202 comprises a gate 201 and a gate oxide layer 203, for example. Wherein, the gate oxide layer 203 is disposed between the gate 201 and a substrate 200. The gate 201 is made of polysilicon, and the gate oxide layer 203 is made of silicon oxide, for example. In addition, a spacer 205 is disposed on a side wall of the gate structure 202, and the spacer 205 is made of silicon oxide or silicon nitride, for example.

The N-type source region 204 is disposed in the substrate 200 at one side of the gate structure 202, and the N-type well region 206 is disposed in the substrate 200 at another side of the gate structure 202. Here, the N-type well region 206 has higher impedance. In addition, the N-type drain region 208 is disposed in the substrate 200 between the N-type well region 206 and the gate structure 202. Wherein, the N-type drain region 208 has a toothed part 209 disposed in the N-type well region 206. Furthermore, the N-doped region 210 disposed in the N-type well region 206 also has a toothed part 211.

In another embodiment of the present invention, a conductive layer 212 is disposed on the N-type source region 204, a part of the gate 201, and a part of the gate 201, a part of the N-doped region 210, and the toothed part 211 are exposed. In other words, the conductive layer 212 is disposed on the gate 201, the N-type source region 204, and the N-doped region 210 outside the salicide block 207 for reducing the impedance. Here, the conductive layer 212 is made of metal silicide, for example.

In addition, a dielectric layer (not shown) is disposed on the substrate 200, and the dielectric layer covers the gate structure 202, the N-type source region 204, the N-type well region 206, the N-type drain region 208, the N-doped region 210, and the substrate 200. Here, the dielectric layer is made of silicon oxide, for example. A drain contact plug (not shown) disposed in the dielectric layer on the N-doped region 210 is electrically coupled to the N-doped region 210. Moreover, a source contact plug (not shown) disposed in the dielectric layer on the N-type source region 204 is electrically coupled to the N-type source region 204. Here, the drain contact plug and the source contact plug that transmit the electrical current are made of metal, for example.

In the present embodiment, since part of the N-type well region 206 is disposed below the conductive layer 212 at the drain side (i.e. a salicide region), the uneven distribution of the electrostatic discharge in the salicide manufacturing process is resolved. In addition, the N-type well region 206 may also work as an output load to provide an even current in the layout mentioned above.

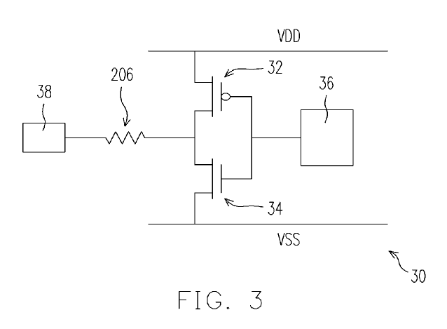

Furthermore, if the semiconductor device mentioned above is serially connected to a PMOS transistor, such circuit can be used as an electrostatic discharge protection device. FIG. 3 is a schematic circuit diagram of an electrostatic discharge protection device according to an embodiment of the present invention. Referring to FIG. 3, the electrostatic discharge protection device 30 mainly comprises a PMOS transistor 32 and an NMOS transistor 34.

Here, the NMOS transistor 34 is the semiconductor device mentioned above (e.g. the one shown in FIGS. 2A and 2B). A gate of the PMOS transistor 32 is electrically coupled to a gate of the NMOS transistor 34, and both gates are electrically coupled to an internal circuit 36. A source of the PMOS transistor 32 is electrically coupled to a power line VDD, and a source of the NMOS transistor 34 is electrically coupled to a power line VSS. In addition, a drain of the NMOS transistor 34 is electrically coupled to a drain of the PMOS transistor 32, and both drains are electrically coupled to an output pin 38 through the N-type well 206.

In general, after the electrostatic is discharged, when the current flows from the drain contact plug to the N-doped region 210 and then to the N-type drain region 208, since both front ends of the N-doped region 210 and the N-type drain region 208 are formed as toothed shape, the current is evenly distributed by the tooth-like parts 211 and 209. In addition, since the N-type well region 206 has higher impedance, the current slowly flows to the N-type drain region 208 from the N-doped region 210. Then, after the current flows to the N-type source region 204, the current then flows out from the power line VSS electrically coupled to the source contact plug.

In summary, an N-type well region with higher impedance is applied in the present invention to slow down the current flow, and an N-type drain region and an N-doped region each with a toothed part are used in the present invention to evenly distribute the current flow, thus the current does not concentrate on a single part to damage the structure of the integrate circuit device. In addition, in the manufacturing process of the electrostatic discharge protection device provided by the present invention, no additional photomask is required, which not only simplifies the manufacturing process but also reduces the manufacturing cost. Furthermore, the present invention also provides an effective layout to reduce the size of the output buffer.

Although the invention has been described with reference to a particular embodiment thereof, it will be apparent to one of the ordinary skills in the art that modifications to the described embodiment may be made without departing from the spirit of the invention. Accordingly, the scope of the invention will be defined by the attached claims not by the above detailed description.

What is claimed is:

1. A semiconductor device, disposed on a substrate suitable for an electrostatic discharge protection circuit; the semiconductor device comprising:
a gate structure, comprising a gate and a gate oxide layer, wherein the gate oxide layer is disposed between the gate and the substrate;
an N-type source region, disposed in the substrate at one side of the gate structure;
an N-type well region, disposed in the substrate at another side of the gate structure;
an N-type drain region, disposed in the substrate between the N-type well region and the gate structure, wherein the N-type drain region has a first toothed part disposed in the N-type well region; and
an N-doped region, disposed in the N-type well region, wherein the N-doped region has a second toothed part.

2. The semiconductor device of claim 1, further comprising a conductive layer disposed on the N-type source region, a part of the gate, and a part of the N-doped region by which the second toothed part of the N-doped region is exposed.

3. The semiconductor device of claim 2, wherein the material of the conductive layer comprising metal silicide.

4. The semiconductor device of claim 1, further comprising a dielectric layer disposed on the substrate, wherein the dielectric layer covers the gate structure, the N-type source region, the N-type well region, the N-type drain region, the N-doped region, and the substrate.

5. The semiconductor device of claim 4, further comprising a drain contact plug disposed in the dielectric layer on the N-doped region.

6. The semiconductor device of claim 4, further comprising a source contact plug disposed in the dielectric layer on the N-type source region.

7. The semiconductor device of claim 1, further comprising a spacer disposed on the side wall of the gate structure.

8. An electrostatic discharge protection device, comprising:
a PMOS transistor having a first gate electrically coupled to an internal circuit, and having a source electrically coupled to a first power line; and
an NMOS transistor, comprising:
a gate structure comprising a second gate and a gate oxide layer, wherein the gate oxide layer is disposed between the second gate and the substrate, and the second gate is electrically coupled to the first gate of the PMOS transistor;
an N-type source region disposed in the substrate at one side of the gate structure and electrically coupled to a second power line;
an N-type well region disposed in the substrate at another side of the gate structure;
an N-type drain region disposed in the substrate between the N-type well region and the gate structure, wherein the N-type drain region is electrically coupled to a drain of the PMOS transistor, and the N-type drain region and the drain of the PMOS transistor are electrically coupled to an output pin, the N-type drain region having a first toothed part disposed in the N-type well region; and
an N-doped region disposed in the N-type well region, wherein the N-doped region has a second toothed part.

9. The electrostatic discharge protection device of claim 8, further comprising a conductive layer, wherein the conductive layer is disposed on the gate structure, the N-type source region, and the N-doped region by which the second toothed part of the N-doped region is exposed.

10. The electrostatic discharge protection device of claim 9, wherein the material of the conductive layer comprising metal silicide.

11. The electrostatic discharge protection device of claim 8, further comprising a dielectric layer disposed on the substrate.

12. The electrostatic discharge protection device of claim 11, further comprising a drain contact plug disposed in the dielectric layer on the N-doped region.

13. The electrostatic discharge protection device of claim 12, further comprising a source contact plug disposed in the dielectric layer on the N-type source region.
